(19) United States
(12) Patent Application Publication
(10) Pub. No.: US 2026/0349033 A1
(43) Pub. Date: Nov. 5, 2026

(54) SCAN CHAIN MANIPULATION TO ACCOMMODATE REDUCTION IN SCAN IN/OUT PINS

(71) Applicant: Analog Devices International Unlimited Company, Limerick (IE)

(72) Inventors: Abhishek KUMAR, Chhattisgarh (IN); Thirukumaran NATRAYAN, Bangalore, Karnataka (IN); Shyam SUNDAR, Bangalore, Karnataka (IN); Saurbh SRIVASTAVA, Bangalore (IN)

(21) Appl. No.: 19/487,396

(22) PCT Filed: May 30, 2024
(86) PCT No.: PCT/EP2024/064955

§ 371 Date: Nov. 24, 2025

Related U.S. Application Data
(60) Provisional application No. 63/469,926, filed on May 31, 2023.

(51) Int. Cl. G01R 31/3185

(52) U.S. Cl. CPC G01R 31/318572; G01R 31/318547

(57) ABSTRACT

An apparatus is provided for pin count reduction in a chip for using across boards. The apparatus includes a circuit configured to bypass a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction. The respective scan pin is any of a scan IN pin and a scan OUT pin.

### BACKGROUND

This disclosure relates generally to semiconductor testing and packaging, more particularly, to scan chain manipulation to accommodate a reduction in the scan IN/OUT pins.

Scan chains are the elements in scan-based test designs that are used to shift-in and shift-out test data. A scan chain is formed by a number of flipflops connected serially with the output of one flipflop connected to the input of another flipflop. The input of the first flipflop is connected to the input pin of the chip (called “scan-in”) from where data is fed. The output of the last flipflop is connected to the output pin of the chip (called “scan-out”) which is used to take the shifted data out. Thus, the scan chains are inserted into designs to shift the test data into the chip and out of the chip. This is done in order to make every point in the chip controllable and observable through a limited number of test patterns.

Scan testing is performed to test stuck-at faults in manufactured devices. Scan testing is also performed to test the paths in the manufactured devices for delay, e.g., to test whether or not each path is working at the functional frequency.

At times, there may come a need to accommodate a reduction in scan IN/OUT pins thus changing the package/pin compatibility which, in turn, changes the input/output (I/O) ring and pin bonding. However, depending on the delivery timeline, such a change can be time prohibitive as the same typically requires scan-stitching to be redone to re-architect the scan pins and possibly requires redoing the place and route stage depending on how far the design has been developed before a change to the design in reduced pin count is proposed.

### SUMMARY

The following presents a simplified summary of one or more aspects in order to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

According to aspects of the disclosure, an apparatus is provided for pin count reduction in a chip for using across boards. The apparatus includes a circuit configured to bypass a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction. The respective scan pin is any of a scan IN pin and a scan OUT pin.

According to other aspects of the disclosure, a method is provided for pin count reduction in a chip for using across boards. The method includes bypassing, by a circuit, a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction. The respective scan pin is any of a scan IN pin and a scan OUT pin.

According to still other aspects of the disclosure, a method is provided for pin count reduction in a chip for using across boards. The method includes forming a circuit to bypass a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction. The respective scan pin is any of a scan IN pin and a scan OUT pin.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, wherein dashed lines may indicate optional elements, and in which:

FIG. 1 is a table for a scan pin layout showing scan chain assignments to scan IN pins and scan OUT pins, in accordance with an example aspect.

FIG. 2 is a block diagram for a compressor architecture, in accordance with an example aspect.

FIG. 3 is block diagram for a compression mode scan strategy using chain XORing, in accordance with an example aspect.

FIG. 4 is a summary table for the compression mode scan strategy (chain XORing) of FIG. 3, in accordance with an example aspect.

FIG. 5 is a block diagram for a fullscan mode chain stitching strategy for a first chain and a second chain, in accordance with an example aspect.

FIG. 6 is a summary table for the fullscan mode strategy of FIG. 5, in accordance with an example aspect.

FIG. 7 is a block diagram for both the compression mode scan strategy of FIG. 3 and the fullscan mode strategy of FIG. 5, respectively, in accordance with various example aspects.

FIG. 8 is a summary table for the compression mode scan strategy of FIG. 3 and the fullscan mode strategy of FIG. 5, respectively, in accordance with an example aspect.

FIG. 9 is a block diagram for both the compression scan mode strategy of FIG. 3 and the fullscan mode strategy of FIG. 5, respectively, in accordance with various example aspects.

FIG. 10 is a block diagram for a combination of compression scan and fullscan modes (for the high pin count mode), in accordance with various example aspects.

FIG. 11 is block diagram for a combination of compression scan and fullscan modes (for the low pin count mode) for a compression scan mode, in accordance with various example aspects.

FIG. 12 is a block diagram for a combination of compression scan and fullscan modes (for the low pin count mode) for a fullscan mode, in accordance with various example aspects.

FIGS. 13-14 are flow diagrams of an example method for pin count reduction, in accordance with various example aspects.

FIGS. 15-16 are flow diagrams of another example method for pin count reduction, in accordance with various example aspects.

FIG. 17 is a block diagram for a high pin count mode scan IN and scan OUT layout, in accordance with an example aspect.

FIG. 18 is a block diagram for a low pin count mode scan IN and scan OUT layout, in accordance with an example aspect.

FIG. 19 is a summary table of reduction in scan IN pins versus scan OUT pins, in accordance with an example aspect.

FIG. 20 is block diagram for a scan IN pin reduction in a compression mode, in accordance with an example aspect.

### DETAILED DESCRIPTION

Aspects of the present disclosure are directed to apparatuses and methods for scan chain manipulation to accommodate reduction in scan IN/OUT pins.

Aspects of the present disclosure provide various circuit configurations that provide alternate pathways that bypass a particular scan OUT pin while nonetheless fully testing the chip through a connection scheme that attaches to a head flipflop through intermediate flipflops to a tail flipflop in a scan chain subject to pin count reduction. As used herein, pin count reduction refers to reducing at least one of the number of inputs pins or output pins that are connected from the chip across boards

Various aspects of the present disclosure may involve a “high pin count mode” and/or a “low pin count mode.” “High pin count mode” will be selected for scan testing the product which is going to be operated/tested in newly designed boards of ADSP-21560/21561/21564/21568. “Low pin count mode” will be selected for scan testing of the same product which is going to be operated/tested in legacy boards of ADSP-21562/21563/21565/21566/21567/21569.

Aspects of the present disclosure allow for readily dealing with changes in package/pin compatibility that changes the I/O ring and the pin bonding. As such, aspects of the present disclosure avoid redoing scan stitching to re-architect the scan pins.

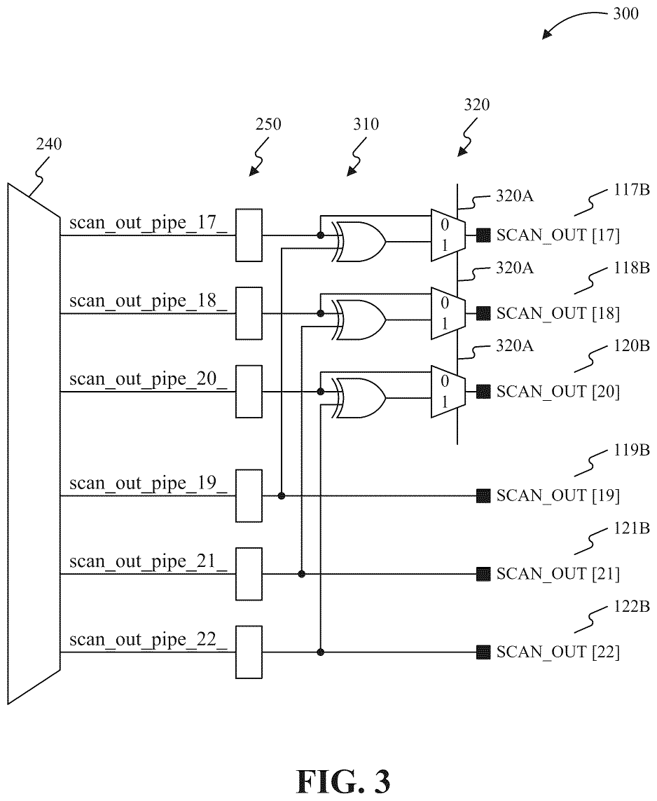

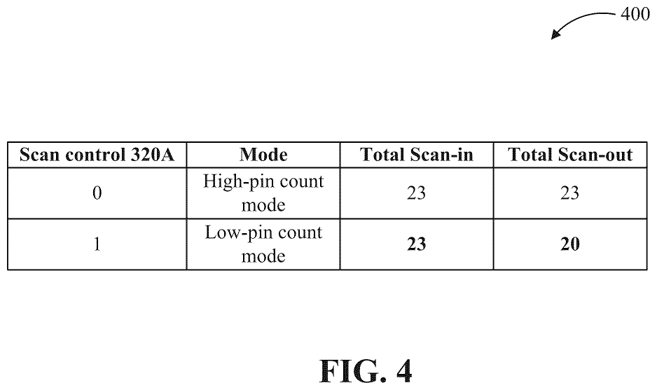

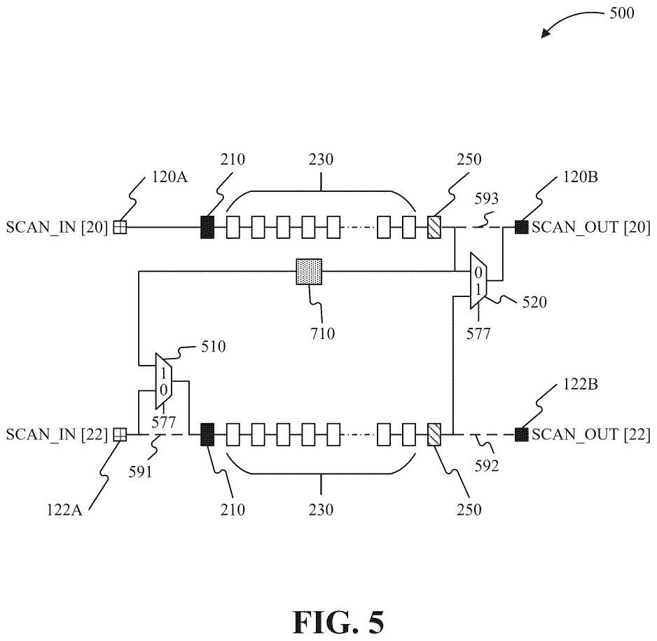

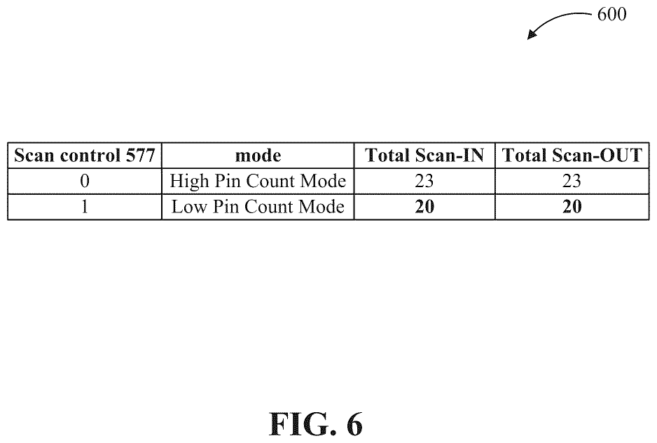

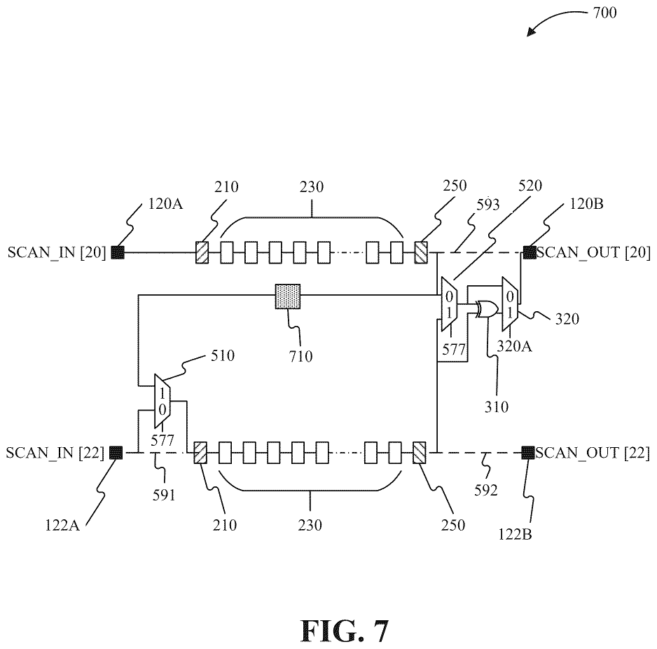

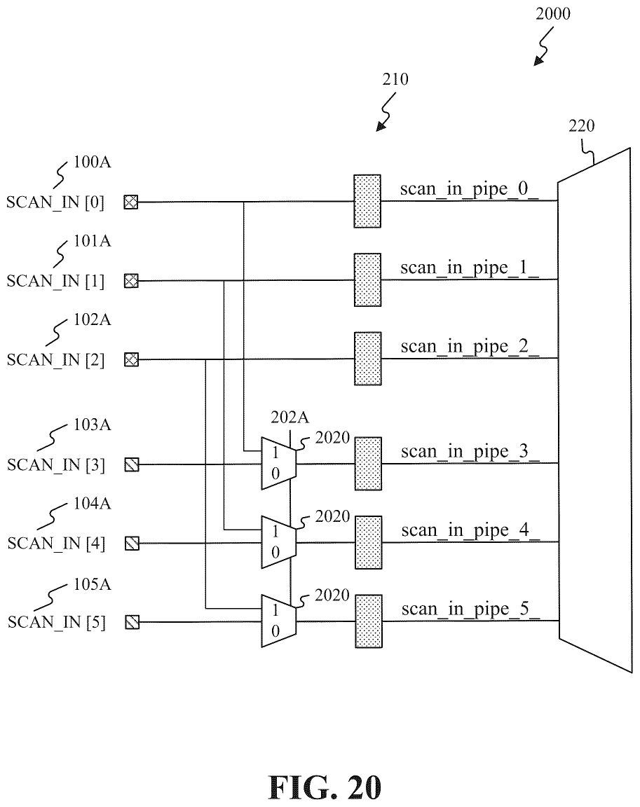

Aspects of the present disclosure can involve selectively bypassing, by a circuit of an apparatus, a scan OUT pin on a scan chain subject to the pin count reduction while maintaining a scan chain flow from a head flipflop through intermediate flipflops to a tail flipflop of the scan chain subject to the pin count reduction, using connections of the circuit to scan chain elements of the scan chain subject to the pin count reduction and scan chain elements of a scan chain not subject to the pin count reduction. The circuit can be any of the following options: (1) first interconnecting pair formed from exclusive-OR gate (hereinafter “XOR”) 310 and multiplexer 320 (see FIGS. 3-4, corresponding to a compression scan mode); (2) second interconnecting pair formed from multiplexer 510 and multiplexer 520 (see FIGS. 5-6, corresponding to a fullscan mode); (3) multiplexer 2020 (see FIG. 20); or (4) options 1 and/or 2 and/or 3 (XOR gate 310, multiplexer 320, multiplexer 510, multiplexer 520, and/or multiplexer 2020) (see FIGS. 7-12, corresponding to a compression scan mode and a fullscan mode).

For example, the compression scan mode supplies test data into multiple internal scan chains from a smaller number of scan-data-input ports and observes the test data from many internal scan chains at a few scan outputs. In accordance with various aspects of the present disclosure, an XOR and a multiplexer are used in compression scan mode to connect a scan chain subject to a pin reduction (having a scan OUT pin not connected to a board) to a scan chain not subject to a pin reduction (having both its scan IN and scan OUT pins connected to a board).

Also, for example, the fullscan mode, also known as the reconfigure mode and non-compression mode, connects all the flip-flops (or registers) to form a shift register by augmenting each flip-flop into a scan flip-flop. A scan flip-flop includes a normal flip-flop and a multiplexer connected to its input. In accordance with various aspects of the present disclosure, a multiplexer interconnected to another multiplexer are used in fullscan mode to connect a scan chain subject to a pin reduction (having a scan OUT pin not connected to a board) to a scan chain not subject to a pin reduction (having both its scan IN and scan OUT pins connected to a board).

As used herein, “pipe head” and “pipeline head” and “head flipflop” all refer to the first flipflop in a scan chain. As used herein, “pipe tail” and “pipeline tail” and “tail flipflop” all refer to the last flipflop in a scan chain. As used herein, “intermediate flipflops” are the flipflops between the pipeline head and the pipeline tail.

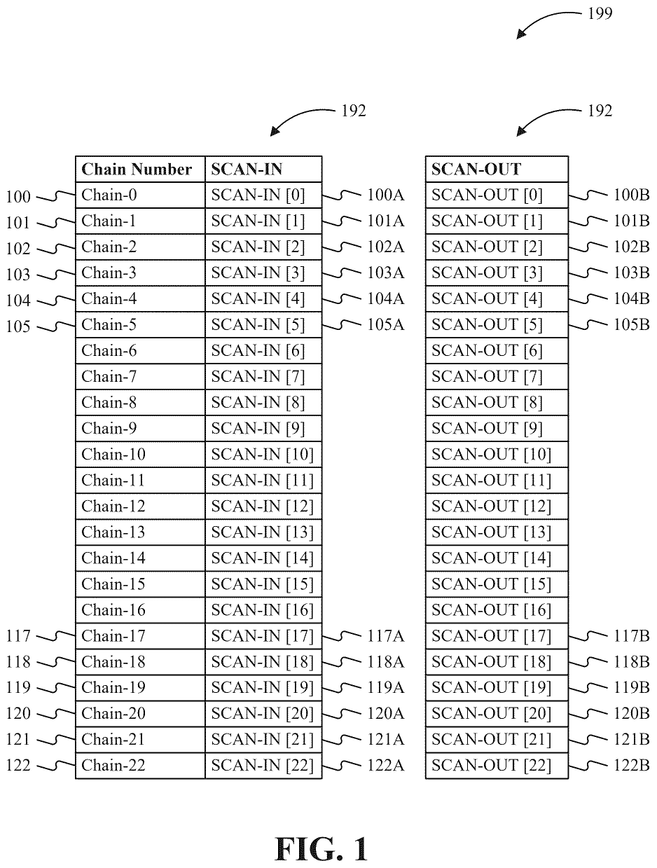

Referring to FIG. 1, a scan pin layout 199 showing scan chain assignments 190 to scan IN pins 191 and scan OUT pins 192, in accordance with an example aspect.

In the scan pin layout 199, the scan out pins for certain signals are being eliminated, that is, scan pin layout 199 defines a pin count reduction. Specifically, in this example, there are 23 fullscan chains in the design (chains 0-22), out of which there is no provision to observe three scan OUT pins (scan OUT 19 (119), 21 (121), and 22 (122) on the low pin count board due to pin unavailability requiring a pin count reduction.

However, the pins cannot be abandoned in scan as it will cause huge coverage losses. In the example of FIG. 1, scan IN pins 117A through 122A and scan OUT pins 117B through 122B are being further described herein for illustrative purposes of the present disclosure.

In further detail, the scan out pin reduction involves a reduction of scan OUT pins 119B, 121B, and 122B in scan chains 19 (119), 21 (121), and 22 (122), respectively. These pins have to be disabled in scan modes to become compatible with a previous product board with lesser pins supported in a possible application scenario. To effect the same, for illustrative purposes, scan chains 17 (177), 18 (118), and 20 (120) are used to implement one or more aspects of present disclosure. However, it is to be appreciated that any other scan chains not having a change in their scan IN/OUT pins can be used with respect to scan OUT pins 119, 121B, and 122B (or whichever pins are being reduced). In the example of FIG. 1, scan chains not having a change in their scan IN/OUT pins include chains 1-18 and 20. The term “not having a change in IN/OUT pins” refers to a scan chain not subject to pin count reduction, that is, having both its scan IN and scan OUT pins connected to the board and not just the scan IN pin like a scan chain subject to pin count reduction whose scan OUT pin is unconnected to the board and/or not just the scan OUT pin like a scan chain subject to a pin count reduction whose scan IN pin is unconnected to the board.

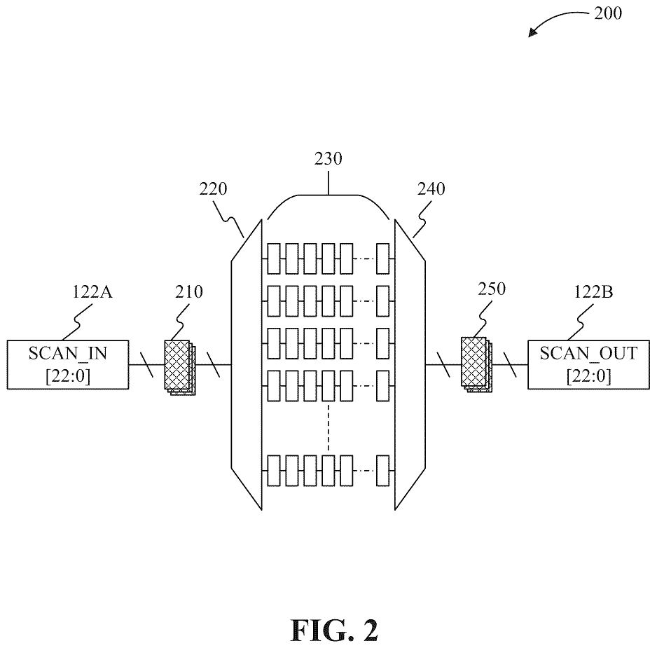

Referring to FIG. 2, a compressor architecture 200 is shown, in accordance with an example aspect.

The scan architecture 200 in this example involves scan chain 22 (122) and scan IN pin 122A and scan OUT pin 122B. Scan chain 22 (122) includes scan IN pin 122A, a pipeline head flipflop 210, a decompressor 220, sets of serially connected intermediate flipflops (hereinafter “intermediate flipflops”) 230, a compressor 240, a pipeline tail flipflop 250, and scan OUT pin 122B. Elements of scan chain architecture 200 are described in further detail hereinbelow.

Referring to FIG. 3, a compression mode scan strategy 300 using chain XORing is shown, in accordance with an example aspect.

From the compressor 240, scan out pipes 17-21 are each connected to a respective pipeline tail flipflop 250. Each pipeline tail flipflop 250 is connected to a first of two inputs to an XOR gate (hereinafter “XOR) 310, with such one input also connected to a first input of a 2:1 multiplexer (hereinafter “mux”) 320. The output of the XOR 310 is connected to the second input of mux 320. The output of the mux 320 is connected to the scan OUT pin 117B. The other input of the XOR 310 is connected, past the pipeline tail flipflop 250, of any other scan chains (e.g., scan chains 1-18 and 20, in this example, one of scan chains 17, 18, or 20) not having a change in their scan IN/OUT pins. In the example of FIG. 3, scan chain 19 (119) is connected to unchanged scan chain 17 (117), scan chain 21 (121) is connected to unchanged scan chain 18 (118), and scan chain 22 (122) is connected to unchanged scan chain 20 (120).

Referring to FIG. 4, a summary table 400 for the compression mode scan strategy (chain XORing) 300 of FIG. 3 is shown, in accordance with an example aspect.

Signal 320A is used as a select for a 2:1 mux to switch between high-pin count mode and low-pin count mode. Signal 320A can be controlled while generating patterns. With this addition in the design, scan patterns can be generated in both modes as shown in the table of FIG. 4.

Referring to FIG. 5, a fullscan mode chain stitching strategy 500 for chain 20 (120) and chain 22 (122) is shown, in accordance with an example aspect.

Scan chain 20 (120) incudes scan IN pin 120A, pipeline head flipflop 210, intermediate flipflops 230, pipeline tail flipflop 250, and scan OUT pin 120B.

Scan chain 22 (122) includes scan IN pin 122A, pipeline head flipflop 210, intermediate flipflops 230, pipeline tail flipflop 250, and scan OUT pin 122B, where scan OUT pin 122B is not used, but instead bypassed, using an arrangement of 2:1 muxes 510 and 520 that are controlled by signal 577.

In particular, mux 510 includes a first input connected to scan IN pin 122A and an output connected to pipeline head flipflop 210, bypassing line portion 591. A second input of mux 510 is connected to a first input of mux 520 that is also connected to pipeline tail flipflop 250 of scan chain 20 (120). The other input of mux 520 is connected to the pipeline tail flipflop 250 of chain 22 (122), bypassing line portion 592 and scan OUT pin 122B. The output of mux 520 is connected to scan OUT pin 120A, bypassing line portion 593.

Referring to FIG. 6, a summary table for the fullscan mode strategy 500 of FIG. 5 is shown, in accordance with an example aspect.

Signal 577 is used as a select for a 2:1 mux to switch between high pin count mode and low pin count mode. Signal 577 can be controlled while generating patterns. With this addition in the design, SCAN patterns can be generated in both modes as shown in the table of FIG. 4.

Referring to FIG. 7, both the compression mode scan strategy 300 of FIG. 3 and the fullscan mode strategy 500 of FIG. 5, respectively, are shown, in accordance with various example aspects. While in some example aspects, the muxes 510, 520, and 320 are used to selected between the 2 modes (the high pin count mode and the low pin count mode), in other aspects various ones of the muxes 510, 520, and 320 can be omitted and replaced with metal lines, wires, and other conductors without the use of switching elements to switch between modes.

As noted above, scan chain 20 (120) incudes scan IN pin 120A, pipeline head flipflop 210, intermediate flipflops 230, pipeline tail flipflop 250, and scan OUT pin 120B.

As noted above, scan chain 22 (122) includes scan IN pin 122A, pipeline head flipflop 210, intermediate flipflops 230, pipeline tail flipflop 250, and scan OUT pin 122B. Scan OUT pin 122B is not used, but instead bypassed, using an arrangement of 2:1 muxes 510 and 520 that are controlled by signal 577 and 2:1 mux 320 that is controlled by signal 320A.

In particular, mux 510 includes a first input connected to scan IN pin 122A and an output connected to pipeline head flipflop 210, selectively bypassing line portion 591. A second input of mux 510 is optionally connected to a lockup latch 710 that, in turn, is connected to a first input of mux 520. The first input of mux 520 is also connected to pipeline tail flipflop 250 of scan chain 20 (120). The other input of mux 520 is connected to the pipeline tail flipflop 250 of chain 22 (122) and an input of XOR 310, selectively bypassing line portion 592 and scan OUT pin 122B. The output of mux 520 is connected to another input of the XOR 310 and an input of 2:1 mux 320. The output of XOR 310 is connected to another input of the mux 320. The output of mux 320 is connected to scan OUT pin 120A, selectively bypassing line portion 593. The lockup latch 710 is optionally used to avoid any possibility of a hold violation as the path connecting the output of pipeline tail flop 250 and input of pipeline head flipflop 210 is an inter-scan clock path.

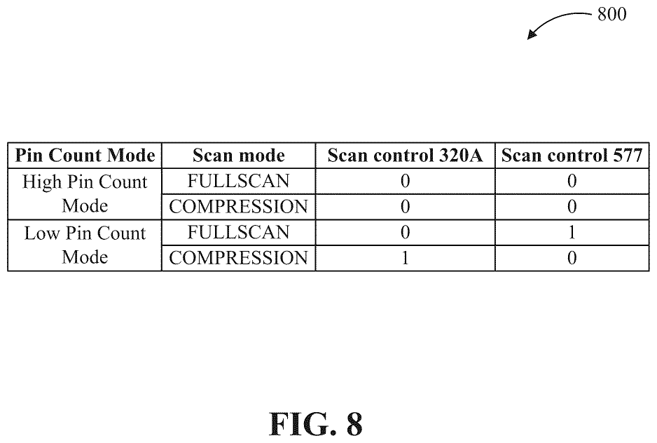

Referring to FIG. 8, a summary table 800 for the compression mode scan strategy 300 of FIG. 3 and the fullscan mode strategy 500 of FIG. 5, respectively, is shown, in accordance with an example aspect.

As is evident, patterns can be generated for both high pin count and low pin count modes, with no issues with scan chain based diagnosis.

In particular, for compression (Low Pin Count Mode), set signal 320A=1, signal 577=0.

For fullscan (Low Pin Count Mode), set signal 320A=0, signal 577=1.

For compression (High Pin Count Mode), set signal 320A=0, signal 577=0.

For fullscan (High Pin Count Mode), set signal 320A=0, signal 577=0.

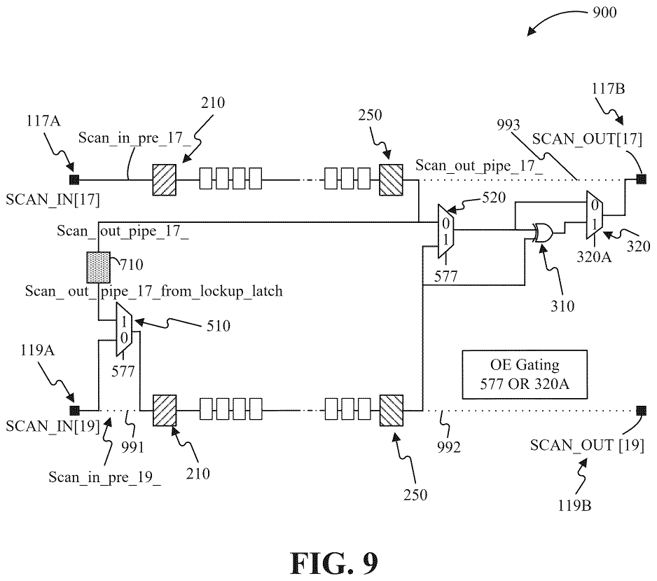

Referring to FIG. 9, both the compression scan mode strategy 300 of FIG. 3 and the fullscan mode strategy 500 of FIG. 5, respectively, are shown, in accordance with various example aspects.

Scan chain 17 (117) incudes scan IN pin 117A, pipeline head flipflop 210, intermediate flipflops 230, pipeline tail flipflop 250, and scan OUT pin 117B.

Scan chain 19 (119) includes scan IN pin 119A, pipeline head flipflop 210, intermediate flipflops 230, pipeline tail flipflop 250, and scan OUT pin 119B. Scan OUT pin 119B is not used, but instead bypassed, using an arrangement of 2:1 muxes 510 and 520 that are controlled by signal 577 and 2:1 mux 320 that is controlled by signal 320A as well as an XOR 310.

In particular, mux 510 includes a first input connected to scan IN pin 119A and an output connected to pipeline head flipflop 210, selectively bypassing line portion 991. A second input of mux 510 is connected to a lockup latch 710 that, in turn, is connected to a first input of mux 520. The first input of mux 520 is also connected to pipeline tail flipflop 250 of scan chain 17 (117). The other input of mux 520 is connected to the pipeline tail flipflop 250 of chain 19 (119) and an input of XOR 310, selectively bypassing line portion 992 and scan OUT pin 119B. The output of mux 520 is connected to another input of the XOR 310 and an input of 2:1 mux 320. The output of XOR 310 is connected to another input of the mux 320. The output of mux 320 is connected to scan OUT pin 117A, selectively bypassing line portion 993.

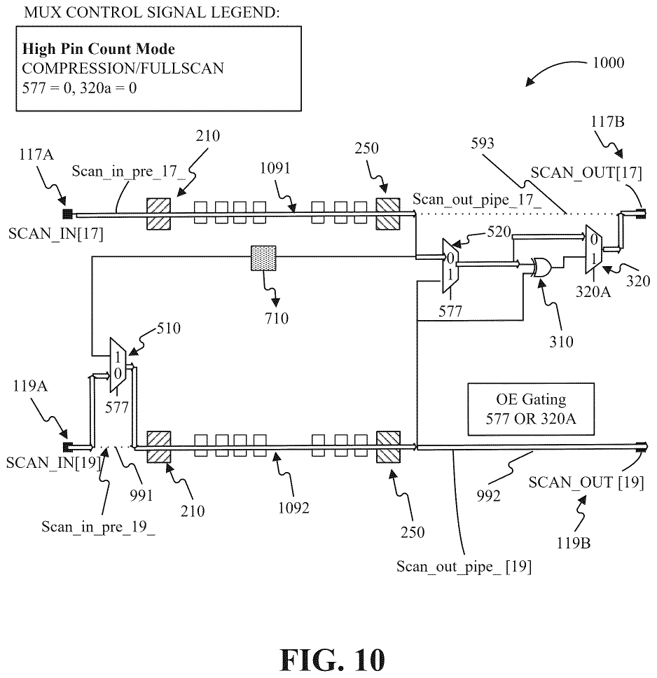

Referring to FIG. 10, a combination 1000 of compression scan and fullscan modes (for the high pin count mode) is shown, in accordance with various example aspects.

In this combination of modes, signal 577 is set to 0 and signal 320A is set to 0.

An alternate path 1091 shows the scan flow through scan chain 17 (117). The alternate path 1091 selectively bypasses wire portion 993 and connects to scan OUT pin 117B, in the combination of compression and fullscan modes (for the high pin count mode).

An alternate path 1092 shows the scan flow through scan chain 19 (119). The alternate path 1092 selectively bypasses wire portion 991 and connects to scan OUT pin 119B, in the combination of compression and fullscan modes (for the high pin count mode).

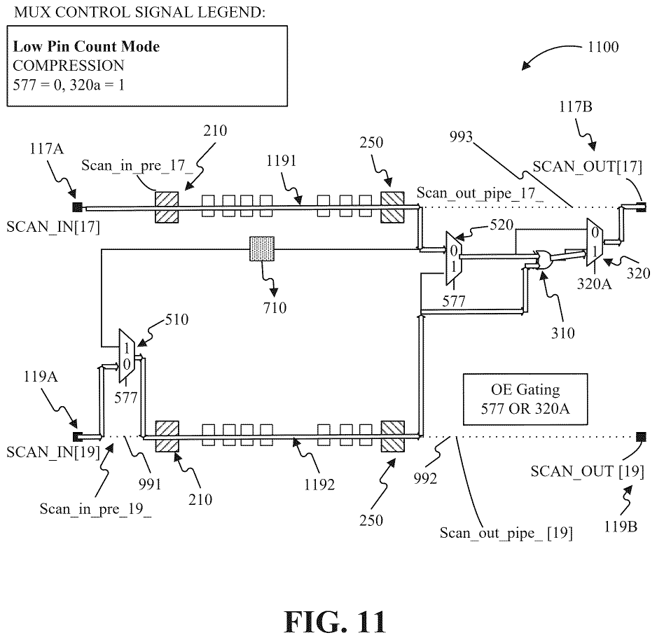

Referring to FIG. 11, a combination 1100 of compression scan and fullscan modes (for the high pin count mode) is shown for compression scan mode, in accordance with various example aspects.

In this combination of modes, signal 577 is set to 0 and signal 320A is set to 1.

An alternate path 1191 shows the scan flow through scan chain 17 (117). The alternate path 1191 selectively bypasses wire portion 993 and connects to scan OUT pin 117B, in the combination of compression and fullscan modes (for the high pin count mode) for compression scan mode.

An alternate path 1192 shows the scan flow through both scan chain 17(117) and scan chain 19 (119). The alternate path 1092 selectively bypasses wire portion 991 and connects to scan OUT pin 117B, in the combination of compression and fullscan modes (for the high pin count mode for a compression scan mode).

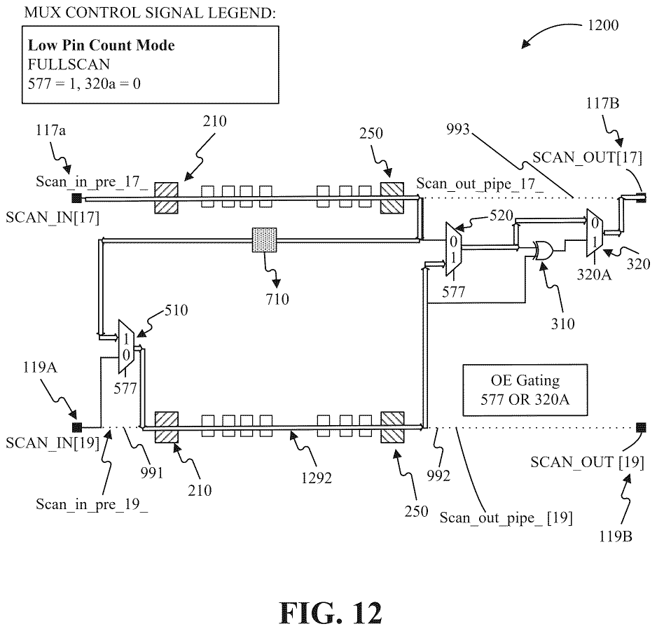

Referring to FIG. 12, a combination 1200 of compression scan and fullscan modes (for the low pin count mode) is shown for a fullscan mode, in accordance with various example aspects.

In this combination of modes, signal 577 is set to 1 and signal 320A is set to 0.

An alternate path 1291 shows the scan flow through scan chain 17 (117). The alternate path 1291 selectively bypasses wire portion 993, in the combination of compression and fullscan modes (for the low pin count mode) for fullscan mode.

An alternate path 1292 shows the scan flow through both scan chain 17 (117) and scan chain 19 (119). The alternate path 1092 selectively bypasses wire portion 991 and wire portion 992 and connects to scan OUT pin 117B, in the combination of compression and fullscan modes (for the low pin count mode) for fullscan mode.

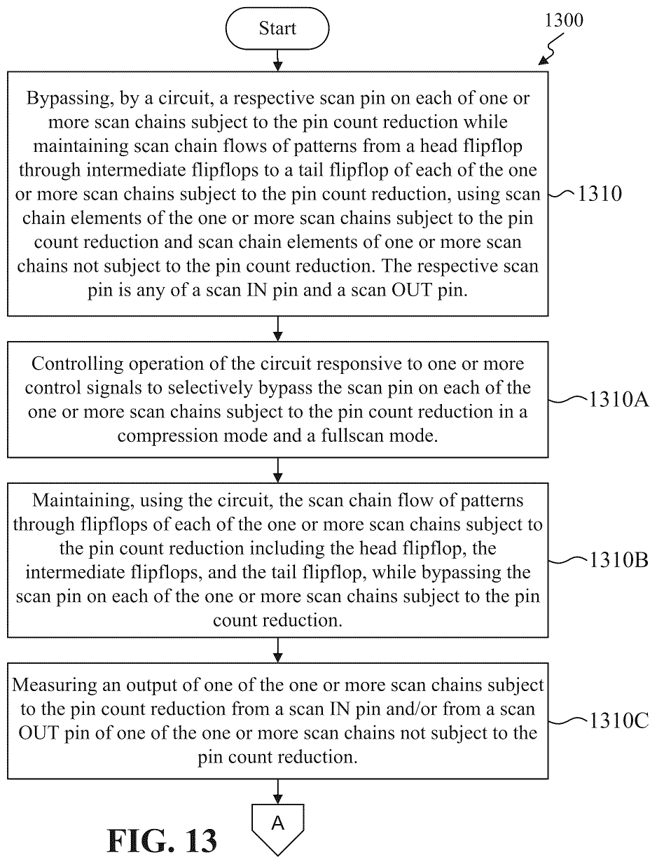

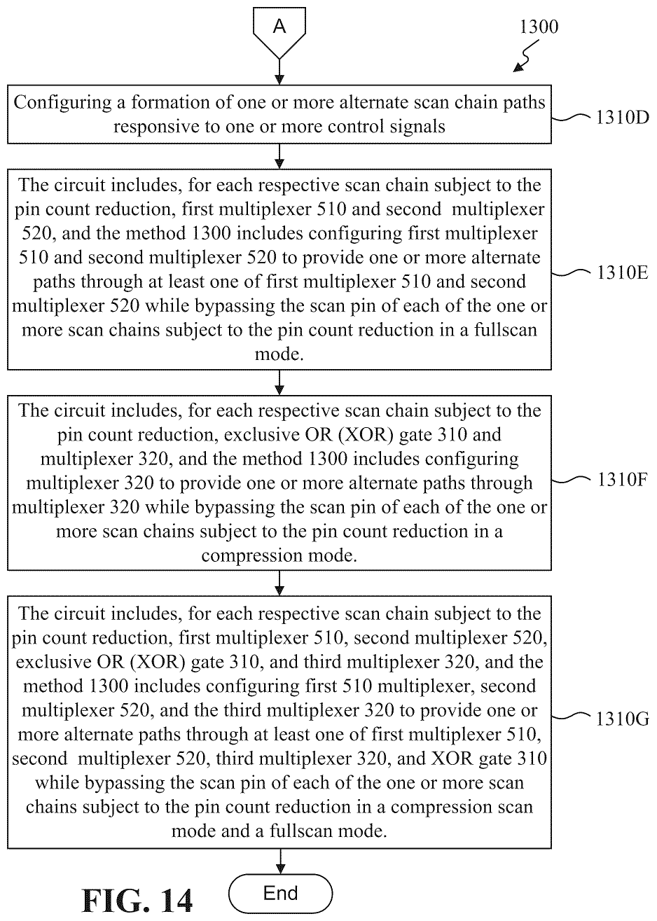

Referring to FIGS. 13-14, an example method 1300 for pin count reduction in a chip for using across boards is shown, in accordance with various example aspects.

At block 1310, the method 1300 includes bypassing, by a circuit, a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction. The respective scan pin is any of a scan IN pin and a scan OUT pin. The circuit can be any of: (1) exclusive OR (XOR) gate 310 and multiplexer 320; (2) multiplexer 510 and multiplexer 520; (3) multiplexer 2020; or (4) options 1 and/or 2 and/or 3 (XOR gate 310, multiplexer 320, multiplexer 510, multiplexer 520, and multiplexer 2020). The bypassing can be selectively performed or implemented in a not switchable manner (e.g., hardwired). Options 1 and 2 relate to bypassing a scan OUT pin, and option 3 relates to bypassing a scan IN pin.

In an aspect, block 1310 may include one or more of blocks 1310A through 1310G.

At block 1310A, the method 1300 includes controlling operation of the circuit responsive to one or more control signals to selectively bypass the scan pin on each of the one or more scan chains subject to the pin count reduction in a compression mode and a fullscan mode.

At block 1310B, the method 1300 includes maintaining, using the circuit, the scan chain flow of patterns through flipflops of each of the one or more scan chains subject to the pin count reduction including the head flipflop, the intermediate flipflops, and the tail flipflop, while bypassing the scan pin on each of the one or more scan chains subject to the pin count reduction.

At block 1310C, the method 1300 includes measuring an output of one of the one or more scan chains subject to the pin count reduction from a scan IN pin and/or from a scan OUT pin of one of the one or more scan chains not subject to the pin count reduction.

At block 1310D, the method 1300 includes (selectively bypassing the respective scan pin of each of the one or more scan chains subject to the pin count reduction by) configuring a formation of one or more alternate scan chain paths responsive to one or more control signals. In an aspect, configuring the formation of the one or more alternate scan chain paths may include enabling a scan chain path from a tail flipflop of one of the one or more scan chains subject to the pin reduction, through a switching element of the circuit, to a scan OUT pin of one of the one or more scan chains not subject to the pin count reduction.

At block 1310E, the circuit includes, for each respective scan chain subject to the pin count reduction, first multiplexer 510 and second multiplexer 520, and the method 1300 includes configuring first multiplexer 510 and second multiplexer 520 to provide one or more alternate paths through at least one of first multiplexer 510 and second multiplexer 520 while bypassing the scan pin of each of the one or more scan chains subject to the pin count reduction in a fullscan mode.

At block 1310F, the circuit includes, for each respective scan chain subject to the pin count reduction, exclusive OR (XOR) gate 310 and multiplexer 320, and the method 1300 includes configuring multiplexer 320 to provide one or more alternate paths through multiplexer 320 while bypassing the scan pin of each of the one or more scan chains subject to the pin count reduction in a compression mode.

At block 1310G, the circuit includes, for each respective scan chain subject to the pin count reduction, first multiplexer 510, second multiplexer 520, exclusive OR (XOR) gate 310, and third multiplexer 320, and the method 1300 includes configuring first 510 multiplexer, second multiplexer 520, and the third multiplexer 320 to provide one or more alternate paths through at least one of first multiplexer 510, second multiplexer 520, third multiplexer 320, and XOR gate 310 while bypassing the scan pin of each of the one or more scan chains subject to the pin count reduction in a compression scan mode and a fullscan mode.

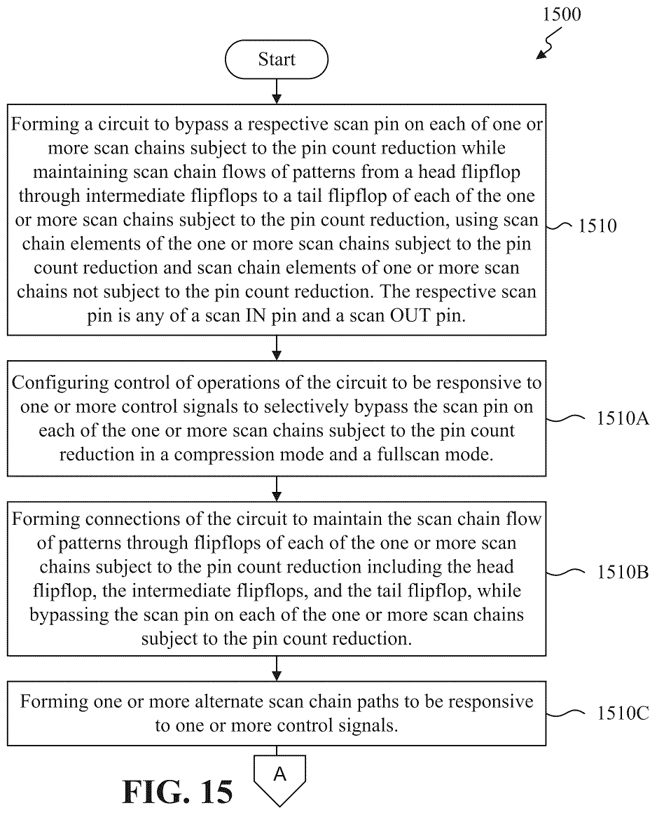

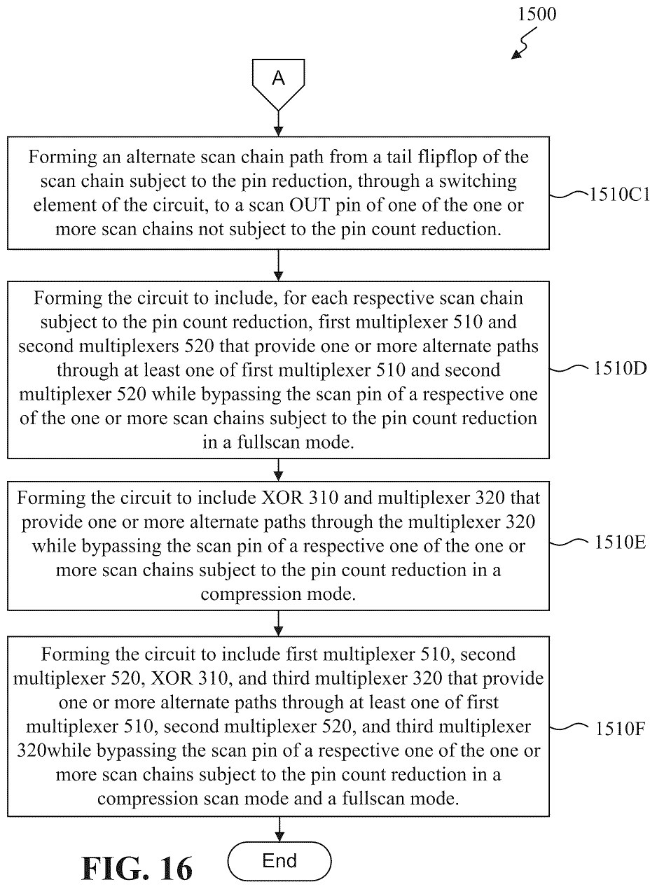

Referring to FIGS. 15-16, another example method 1500 for pin count reduction is shown, in accordance with various example aspects.

At block 1510, the method 1500 includes forming a circuit to bypass a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction. The respective scan pin is any of a scan IN pin and a scan OUT pin.

It is to be appreciated that the forming of block 1510 and other blocks herein refer to the creation of a circuit in a scan chain to alter the pattern flow through the scan chain. It is to be further appreciated that to that end, any methodology for creating a circuit with the elements as described herein may be used, as the inventive aspect do not reside the specific method of circuit creation, but in the configuration of elements formed by such circuit.

In an aspect, block 1510 may include one or more of blocks 1510A through 1510F.

At block 1510A, the method 1500 includes configuring control of operations of the circuit to be responsive to one or more control signals to selectively bypass the scan pin on each of the one or more scan chains subject to the pin count reduction in a compression mode and a fullscan mode.

At block 1510B, the method 1500 includes forming connections of the circuit to maintain the scan chain flow of patterns through flipflops of each of the one or more scan chains subject to the pin count reduction including the head flipflop, the intermediate flipflops, and the tail flipflop, while bypassing the scan pin on each of the one or more scan chains subject to the pin count reduction.

At block 1510C, the method 1500 includes forming one or more alternate scan chain paths to be responsive to one or more control signals.

In an aspect, block 1510C may include block 1510C1.

At block 1510C1, the method 1500 includes forming an alternate scan chain path from a tail flipflop of the scan chain subject to the pin reduction, through a switching element of the circuit, to a scan OUT pin of one of the one or more scan chains not subject to the pin count reduction.

At block 1510D, the method 1500 includes forming the circuit to include, for each respective scan chain subject to the pin count reduction, first multiplexer 510 and second multiplexers 520 that provide one or more alternate paths through at least one of first multiplexer 510 and second multiplexer 520 while bypassing the scan pin of a respective one of the one or more scan chains subject to the pin count reduction in a fullscan mode.

At block 1510E, the method 1500 includes forming the circuit to include, for each respective scan chain subject to the pin count reduction, XOR 310 and multiplexer 320 that provide one or more alternate paths through the multiplexer 320 while bypassing the scan pin of a respective one of the one or more scan chains subject to the pin count reduction in a compression mode.

At block 1510F, the method 1500 includes forming the circuit to include, for each respective scan chain subject to the pin count reduction, first multiplexer 510, second multiplexer 520, XOR 310, and third multiplexer 320 that provide one or more alternate paths through at least one of first multiplexer 510, second multiplexer 520, and third multiplexer 320 while bypassing the scan pin of a respective one of the one or more scan chains subject to the pin count reduction in a compression scan mode and a fullscan mode.

While FIGS. 13-16 and 20 show the use of multiplexers and/or an XOR to implement various aspects of the present disclosure, in another aspects, one or more of the multiplexers can be omitted, and connections shown herein involving the multiplexers can be implemented by wire, metal lines, and so forth. The multiplexers (520 and/or 510 and/or 320 and/or 2020) are to provide flexibility in choosing different circuit configurations with the help of control signals (577, 320A and 2020A) as select lines, hence the multiplexors can be omitted in various aspects.

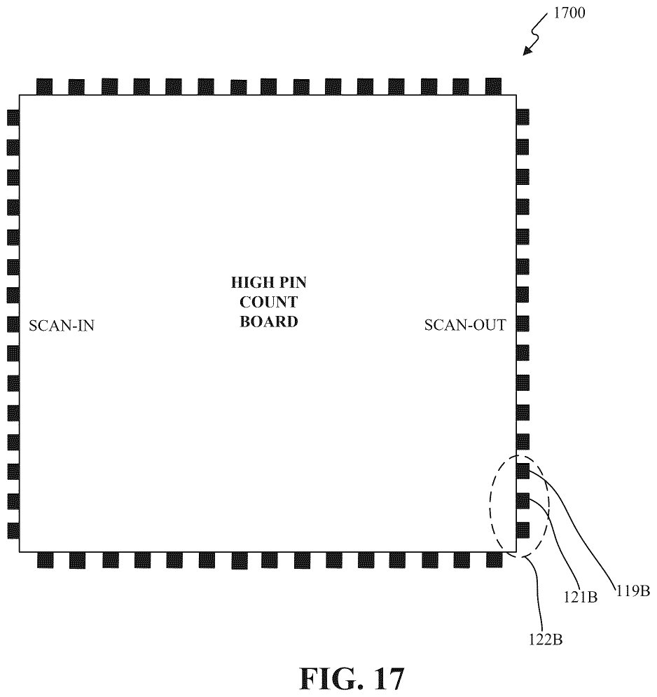

FIG. 17 is a block diagram for a high pin count board scan IN and scan OUT layout 1700, in accordance with an example aspect.

As shown, the high pin count board scan IN and scan OUT layout 1700 includes scan OUT pins 119B, 121B, and 122B.

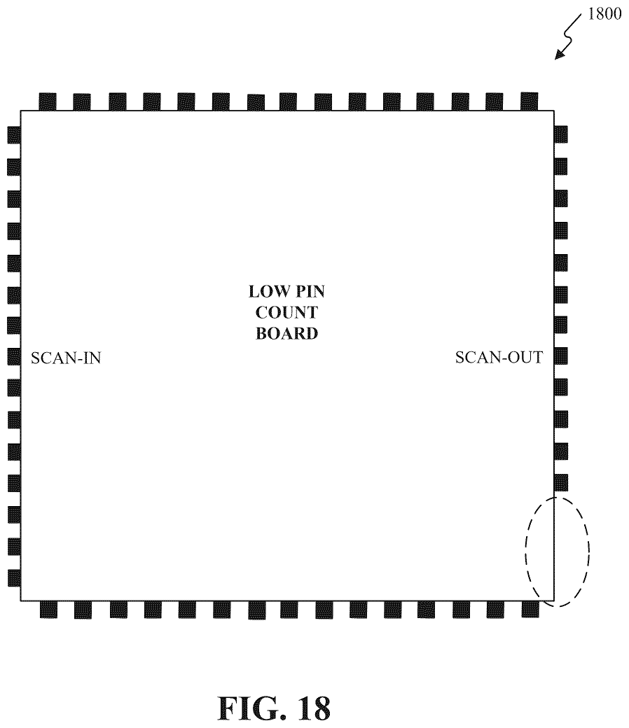

FIG. 18 is a block diagram for a low pin count board scan IN and scan OUT layout 1800, in accordance with an example aspect.

As shown, the low pin count board scan IN and scan OUT layout 1800 omits scan OUT pins 119B, 121B, and 122B.

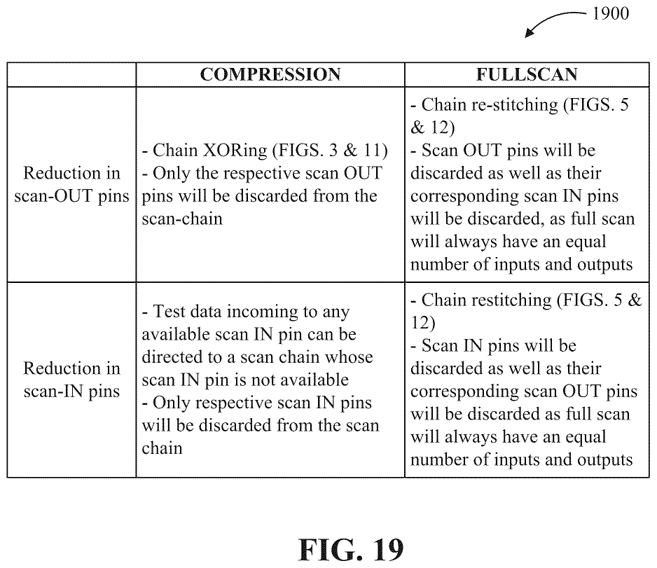

Referring to FIG. 19, a summary table 1900 of reduction in scan IN pins versus scan OUT pins is shown, in accordance with an example aspect.

Regarding a reduction in scan OUT pins in compression scan mode, chain XORing per FIGS. 3 and 11 may be used, where only the respective scan OUT pins will be discarded from the scan chain.

Regarding a reduction in scan OUT pins in fullscan mode, chain re-stitching per FIGS. 5 and 12 may be used, where only scan OUT pins will be discarded as well as their corresponding scan IN pins will be discarded as fullscan will always have an equal number of inputs and outputs.

Regarding a reduction in scan IN pins in compression scan mode, test data incoming to any available scan IN pins can be directed to a scan chain whose scan IN pin is not available (see FIG. 20). Only respective scan IN pins will be discarded from a scan chain.

Regarding a reduction in scan IN pins in fullscan mode, chain re-stitching per FIGS. 5 and 12 may be used, where only scan IN pins will be discarded as well as their corresponding scan OUT pins will be discarded as fullscan will always have an equal number of inputs and outputs.

Referring to FIG. 20, a scan IN pin reduction 2000 in compression mode is shown, in accordance with an example aspect. The scan IN pin reduction strategy in compression mode has been shown for scan IN pin 103A, scan IN pin 104A, and scan IN pin 105A.

Test data incoming to any available scan-IN pins (which are not subjected to pin reduction) can be directed to a scan chain whose scan-in is subjected to pin reduction. For example, data incoming to scan IN[0] 100A will be directed to scan-chain-3 103. Data incoming to scan IN[1] 101A will be directed to scan-chain-4 104. Data incoming to scan IN[2] 102A will be directed to scan-chain-5 105.

The scan IN pin reduction 2000 involves coupling scan_in_pipe_0 to scan_in_pipe_3, scan_in_pipe_1 to scan_in_pipe_4, and scan_in_pipe_2 to scan_in_pipe_5, using multiplexers 2020. In this way, scan IN pin 103A, scan IN pin 104A, and scan IN pin 105A can be bypassed using scan IN pin 100A, scan IN pin 101A, and scan IN pin 102A. However, it is to be appreciated that the flipflops (including head flipflops 210, intermediate flip flows, and tail flipflops) of the scan chains subject to the pin reduction (scan chains 103, 104, and 105) are all subjected to test patterns.

It should be noted that all of the specifications, dimensions, and relationships outlined herein (e.g., the number of elements, operations, steps, etc.) have only been offered for purposes of example and teaching only. Such information may be varied considerably without departing from the spirit of the present disclosure, or the scope of the appended claims. The specifications apply only to one non-limiting example and, accordingly, they should be construed as such. In the foregoing description, example aspects have been described with reference to particular component arrangements. Various modifications and changes may be made to such aspects without departing from the scope of the appended claims. The description and drawings are, accordingly, to be regarded in an illustrative rather than in a restrictive sense.

Note that with the numerous examples provided herein, interaction may be described in terms of two, three, four, or more electrical components. However, this has been done for purposes of clarity and example only. It should be appreciated that the system may be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and may accommodate a large number of components, as well as more complicated/sophisticated arrangements and configurations. Accordingly, the examples provided should not limit the scope or inhibit the broad teachings of the electrical circuits as potentially applied to myriad other architectures.

It should also be noted that in this Specification, references to various features (e.g., elements, structures, modules, components, steps, operations, characteristics, etc.) included in “one aspect”, “example aspect”, “an aspect”, “another aspect”, “some aspects”, “various aspects”, “other aspects”, “alternative aspect”, and the like are intended to mean that any such features are included in one or more aspects of the present disclosure, but may or may not necessarily be combined in the same aspects.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

It should also be noted that the functions related to circuit architectures illustrate only some of the possible circuit architecture functions that may be executed by, or within, systems illustrated in the FIGURES. Some of these operations may be deleted or removed where appropriate, or these operations may be modified or changed considerably without departing from the scope of the present disclosure. In addition, the timing of these operations may be altered considerably. The preceding operational flows have been offered for purposes of example and discussion. Substantial flexibility is provided by aspects described herein in that any suitable arrangements, chronologies, configurations, and timing mechanisms may be provided without departing from the teachings of the present disclosure.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

Note that all optional features of the device and system described above may also be implemented with respect to the method or process described herein and specifics in the examples may be used anywhere in one or more aspects.

The “means for” in these instances (above) may include (but is not limited to) using any suitable component discussed herein, along with any suitable software, circuitry, hub, computer code, logic, algorithms, hardware, controller, interface, link, bus, communication pathway, etc.

Note that with the example provided above, as well as numerous other examples provided herein, interaction may be described in terms of two, three, or four network elements. However, this has been done for purposes of clarity and example only. In certain cases, it may be easier to describe one or more of the functionalities of a given set of flows by only referencing a limited number of network elements. It should be appreciated that topologies illustrated in and described with reference to the accompanying FIGURES (and their teachings) are readily scalable and may accommodate a large number of components, as well as more complicated/sophisticated arrangements and configurations. Accordingly, the examples provided should not limit the scope or inhibit the broad teachings of the illustrated topologies as potentially applied to myriad other architectures.

It is also important to note that the steps in the preceding flow diagrams illustrate only some of the possible signaling scenarios and patterns that may be executed by, or within, communication systems shown in the FIGURES. Some of these steps may be deleted or removed where appropriate, or these steps may be modified or changed considerably without departing from the scope of the present disclosure. In addition, a number of these operations have been described as being executed concurrently with, or in parallel to, one or more additional operations. However, the timing of these operations may be altered considerably. The preceding operational flows have been offered for purposes of example and discussion. Substantial flexibility is provided by communication systems shown in the FIGURES in that any suitable arrangements, chronologies, configurations, and timing mechanisms may be provided without departing from the teachings of the present disclosure.

Although the present disclosure has been described in detail with reference to particular arrangements and configurations, these example configurations and arrangements may be changed significantly without departing from the scope of the present disclosure. For example, although the present disclosure has been described with reference to particular communication exchanges, aspects described herein may be applicable to other architectures.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 142 as it exists on the date of the filing hereof unless the words “means for” or “step for” are specifically used in the particular claims; and (b) does not intend, by any statement in the specification, to limit this disclosure in any way that is not otherwise reflected in the appended claims.

1. An apparatus for pin count reduction in a chip for using across boards, the apparatus comprising:
a circuit configured to bypass a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction,
wherein the respective scan pin is any of a scan IN pin and a scan OUT pin.

2. The apparatus according to claim 1, wherein the circuit is configured to selectively bypass the respective scan pin using, for each of the one or more chain scans subject to the pin count reduction, at least one of: a first interconnected pair formed from two multiplexers;
and a second interconnected pair formed from a multiplexer and a logic gate.

3. The apparatus of claim 2, wherein the first interconnected pair is connected to the second interconnected pair.

4. The apparatus according to claim 1, wherein the circuit is configured to selectively bypass the pin on each of the one or more scan chains subject to the pin count reduction in at least one of a compression mode and a fullscan mode.

5. The apparatus according to claim 1, wherein the circuit is connected to a scan IN pin of at least one of the one or more scan chains not subject to the pin count reduction while bypassing a scan IN pin of at least one of the one or more scan chains subject to the pin count reduction.

6. The apparatus according to claim 1, wherein the circuit is connected to a scan OUT pin of at least one of the one or more scan chains not subject to the pin count reduction while bypassing a scan OUT pin of at least one of the one or more scan chains subject to the pin count reduction.

7. The apparatus according to claim 1, wherein the circuit comprises, for each of the one or more scan chains subject to the pin count reduction, a first multiplexer and a second multiplexer configured for use in a compression scan mode.

8. The apparatus according to claim 7, wherein the first multiplexer and the second multiplexer enable one or more alternate paths through the chip.

9. The apparatus according to claim 7, wherein the circuit further comprises, for each of the one or more scan chains subject to the pin count reduction, an exclusive-or (XOR) gate and a third multiplexer connected to the second multiplexer.

10. The apparatus according to claim 9, wherein an output of the XOR gate is connected to a first input of the third multiplexer and a second input of the third multiplexer is connected to an output of the second multiplexer.

11. The apparatus according to claim 7, wherein the first multiplexer is connected to a head flipflop of a respective one of the one or more scan chains subject to the pin count reduction and to a tail flipflop of a respective one of the one or more scan chains not subject to the pin count reduction, wherein the second multiplexer is connected to the tail flipflop of the respective one of the one or more scan chains not subject to the pin count reduction and connected to the tail flipflop of the respective one of the one or more scan chains subject to the pin count reduction.

12. The apparatus according to claim 7, wherein the circuit comprises, for each of the one or more scan chains subject to the pin count reduction, an exclusive-or (XOR) gate and a multiplexer configured for use in a compression mode.

13. The apparatus according to claim 12, wherein an output of the XOR gate is connected to an input of the multiplexer.

14. The apparatus according to claim 12, wherein the circuit comprises, for each of the one or more scan chains subject to the pin count reduction, a first 2:1 multiplexer configured to selectively bypass a scan OUT pin on the one or more scan chains subject to the pin count reduction in a compression mode and having:
a first input connected to a scan IN pin of one of the one or more scan chains subject to the pin count reduction; and
an output connected to an input of the head flipflop of the one or more scan chains subject to the pin count reduction.

15. The apparatus according to claim 12, wherein the circuit comprises, for each of the one or more scan chains subject to the pin count reduction, a multiplexer configured to selectively bypass a scan IN pin on the one or more scan chains subject to the pin count reduction, the multiplexer having an input connected to the scan IN pin on one of the one or more scan chains subject to the pin count reduction and having another input connected to the scan IN pin on one of the one or more scan chains not subject to the pin count reduction.

16. A method for pin count reduction in a chip for using across boards, the method comprising:
bypassing, by a circuit, a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction,
wherein the respective scan pin is any of a scan IN pin and a scan OUT pin.

17. The method according to claim 16, further comprising controlling operation of the circuit responsive to one or more control signals to selectively bypass the respective
scan pin on each of the one or more scan chains subject to the pin count reduction in at least one of a compression mode and a fullscan mode.

18. The method according to claim 16 further comprising measuring an input of one of the one or more scan chains subject to the pin count reduction from a scan IN pin of one of the one or more scan chains not subject to the pin count reduction.

19. The method according to claim 16, further comprising measuring an output of one of the one or more scan chains subject to the pin count reduction from a scan OUT pin of one of the one or more scan chains not subject to the pin count reduction.

20. The method according to claim 16, wherein the circuit comprises, for each of the one or more scan chains subject to the pin count reduction, a first interconnected multiplexer and a second interconnected multiplexer, and
wherein the method further comprises configuring the first and the second interconnected multiplexers to provide one or more alternate paths through the chip while selectively bypassing the respective scan pin of each of the one or more scan chains subject to the pin count reduction in a compression scan mode.

21. The method according to claim 16,
wherein the circuit comprises, for each of the one or more scan chains subject to the pin count reduction, an exclusive OR (XOR) gate and a multiplexer, and
wherein the method further comprises configuring the multiplexer to provide one or more alternate paths through the chip while selectively bypassing the respective scan pin of the scan chain subject to the pin count reduction in a fullscan mode.

22. The method according to claim 16,
wherein the circuit comprises, for each of the one or more scan chains subject to the pin count reduction, a first interconnected multiplexer and a second interconnected multiplexer, an exclusive OR (XOR) gate, and a multiplexer, and
wherein the method further comprises configuring the first interconnected multiplexer, the second interconnected multiplexer, and the multiplexer to provide one or more alternate paths through the first interconnected multiplexer, the second interconnected multiplexer, and the multiplexer while bypassing the respective scan pin of a respective one of the one or more scan chains subject to the pin count reduction in a fullscan mode.

23. The method according to claim 16, wherein the circuit comprises, for each of the one or more scan chains subject to the pin count reduction, a multiplexer configured to selectively bypass a scan IN pin on one of the one or more scan chains subject to the pin count reduction, and wherein the method further comprises configuring the multiplexer to provide one or more alternate paths through the multiplexer while bypassing the scan IN pin on the one of the one or more scan chains subject to the pin count reduction.

24. A method for pin count reduction in a chip for using across boards, the method comprising:
forming a circuit to bypass a respective scan pin on each of one or more scan chains subject to the pin count reduction while maintaining scan chain flows of patterns from a head flipflop through intermediate flipflops to a tail flipflop of each of the one or more scan chains subject to the pin count reduction, using scan chain elements of the one or more scan chains subject to the pin count reduction and scan chain elements of one or more scan chains not subject to the pin count reduction,
wherein the respective scan pin is any of a scan IN pin and a scan OUT pin.

25. The method according to claim 24, further comprising configuring control of operations of the circuit to be responsive to one or more control signals to selectively bypass the pin on the one or more scan chains subject to the pin count reduction in a compression mode and a fullscan mode.

26. The method according to claim 24, further comprising configuring an output of one of the one or more scan chains subject to the pin count reduction to be measured from a scan IN pin of one of the one or more scan chains not subject to the pin count reduction.

27. The method according to claim 24, further comprising configuring an output of one of the one or more scan chains subject to the pin count reduction to be measured from a scan OUT pin of one of the one or more scan chains not subject to the pin count reduction.

28. The method according to claim 24, further comprising forming one or more alternate scan chain paths to be responsive to one or more control signals.

29. The method according to claim 28, wherein forming the one or more alternate scan paths comprises forming an alternate scan chain path from the tail flipflop of the scan chain subject to the pin reduction, through a switching element of the circuit, to a scan OUT pin of one of the one or more scan chains not subject to the pin count reduction.

30. The method according to claim 24, further comprising forming the circuit to include, for each of the one or more scan chains subject to the pin count reduction, a first multiplexer and a second multiplexer that provide one or more alternate paths through at least one of the first multiplexer and the second multiplexer in a compression scan mode.

31. The method according to claim 24, further comprising forming the circuit to include, for each of the one or more scan chains subject to the pin count reduction, an exclusive OR (XOR) gate and a multiplexer that provide one or more alternate paths through the multiplexer in a fullscan mode.

32. The method according to claim 24, further comprising forming the circuit to include, for each of the one or more scan chains subject to the pin count reduction, a first multiplexer, a second multiplexer, a third multiplexer, and an exclusive OR (XOR) gate that provide one or more alternate paths through at least one of the first multiplexer, the second multiplexer, the third multiplexer, and the XOR gate in a compression scan mode and a fullscan mode.

33. The method according to claim 24, further comprising forming the circuit to include, for each of the one or more scan chains subject to the pin count reduction, a multiplexer that provides one or more alternate paths through the multiplexer in a compression scan mode and a fullscan mode.
